(19) United States
(12) Patent Application Publication
(10) Pub. No.: US 2011/0068354 A1
(43) Pub. Date: Mar. 24, 2011

(54) High power LED lighting device using high extraction efficiency photon guiding structure

(75) Inventors: Nguyen The Tran, Garden Grove, CA (US); Yongzhi He, Irvine, CA (US)

(73) Assignee: SHILED Group International, Irvine, CA (US)

(21) Appl. No.: 12/586,264

(22) Filed: Sep. 19, 2009

(51) Int. Cl. H01L 33/00; C09K 11/59

(52) U.S. Cl. 257/89; 252/301.4 F; 257/98; 257/E33.061; 257/E33.067

(57) ABSTRACT

The present invention discloses a high power light emitting device using a high extraction efficiency photon-guiding structure for producing high-efficiency white light output with large viewing angle and large amount of light emitted from the side surfaces so that they can provide different light patterns for different applications such as street lighting, parking lighting, tunnel lighting, and etc., as they are used with a reflector. The emitter consists of a leadframe package or chip-on-board substrate, plurality of LED chips, silicone encapsulation material containing phosphor materials to convert short wavelength LED-emanated light to longer wavelength of light, a photon-guiding structure that enhances the efficiency of the LED package and provides light output with large viewing angle.

The application is related to an expired provisional application with the application number of U.S. 61/131,563 filed on Jun. 10, 2008.

### BACKGROUND OF INVENTION

1. Field of the Invention

The invention relates to high power light emitting diode device using high extraction efficiency photon guiding structure for producing high-efficiency white light output with large viewing angle and large amount of light emitted from the side surfaces so that they can provide different light patterns for different applications such as street lighting, parking lighting, tunnel lighting, and etc., as they are used with a reflector.

2. Background Art

Light emitting diodes (LEDs) can emit different colors of light. For producing white light, various colors can be combined. The common way for producing white LED (WLED) light is to use phosphor materials that absorb blue LED-emanated light and emit yellow or greenish yellow light. With an increase in the adoption of WLEDs into different lighting applications such as home lighting, industrial lighting, office lighting, tunnel light, and street lighting that require high power, low power WLED is not appropriate since low power LEDs for these applications can increase manufacturing cost associated with equipment investment and assembly cost. Therefore, high power LED packages are required.

In conventional phosphor-based high power WLED packages, light is often trapped inside the package, resulting in a low efficiency and lifetime. The conventional WLED package usually uses a hemispherical lens structure to improve light extraction and efficiency. This hemispherical lens or convex lens is appropriate for relatively low power package that has small size but it is not appropriate for high power or large emitting area package, especially extreme high power package. This structure still does not achieve maximum extractable level, increases material cost, and is bulky to use this structure in high power or large emitting area package. Moreover, this hemispherical lens or convex lens for extreme high power LED package results in reliability problem. Therefore, high power or large emitting area package usually has a low-extraction flat surface of encapsulant dispensed in a recess region of a reflection cup as an extraction structure.

Another issue with conventional high power WLED packages is angular light distribution. The conventional high power WLED package usually has emitted light concentrating within low viewing angle or a small solid angle. It is thus difficult to control light pattern and to provide wide view angle with uniform intensity distribution for foregoing applications.

### SUMMARY OF THE INVENTION

The present invention is to provide an LED lighting device for providing white light with high efficiency, high uniform color/CCT distribution in space, and large viewing angle so that it can be used with a reflector to control light pattern for different applications such as street lighting, parking lighting, and tunnel lighting. The LED light device includes a substrate, a supporting structure, encapsulation layer, photon-extraction structure, and a plurality of LED chips forming at least one array of linear LED chips. Blue light emanated from LED chips is partially absorbed by phosphor materials followed by emission of orange and/or red light, and/or greenish-yellow light by phosphor materials. The phosphor materials emitting different color types of light can form each individual layer with the layer closer to the LED chips containing phosphor particles that emit light at a longer wavelength of light such as red light and orange light.

Emitted light is not only emitted from the top surface of the optical structure but also on the side surfaces of the optical structure, resulting in more light emitted in high viewing angle.

The top surface of the optical part of the device can be a curved surface to direct more light to the side surfaces, resulting in emitted light with large viewing angle.

### BRIEF DESCRIPTION OF THE DRAWINGS

FIG. 1 is a perspective view of an LED of the invention

FIG. 2 is a cross-section view of a lead-frame as an example of lead-frame for this invention

FIG. 3 is a cross-section view of a LED device as an example of the LED device described in this invention

FIG. 4 is a schematic drawing of a cross-section view of the photon-extraction structure with multilayer of phosphors

FIG. 5 is a cross-section view of a LED device as an example of the LED device described in an alternative embodiment of the invention

FIG. 6: a schematic drawing of top encapsulation or cover lens as an alternative embodiment of the LED packages shown in FIGS. 3 and 5

FIG. 7: angular intensity distribution of light output from a conventional extreme power (100 W) LED packages (dash line) and the 100 W LED package of the invention (solid line)

### DETAILED DESCRIPTION OF THE INVENTION

This invention discloses a lighting device with a high extraction efficiency photon guiding structure for generating white light with wide viewing angle that can be used with conventional fixture to generate light pattern that can be used in various application such as street lighting, parking lighting, tunnel lighting, and etc. With high amount of light emitted from the side, the light emitted from the LED device of the invention can be easily directed to desired direction by using conventional lighting fixture or reflector.

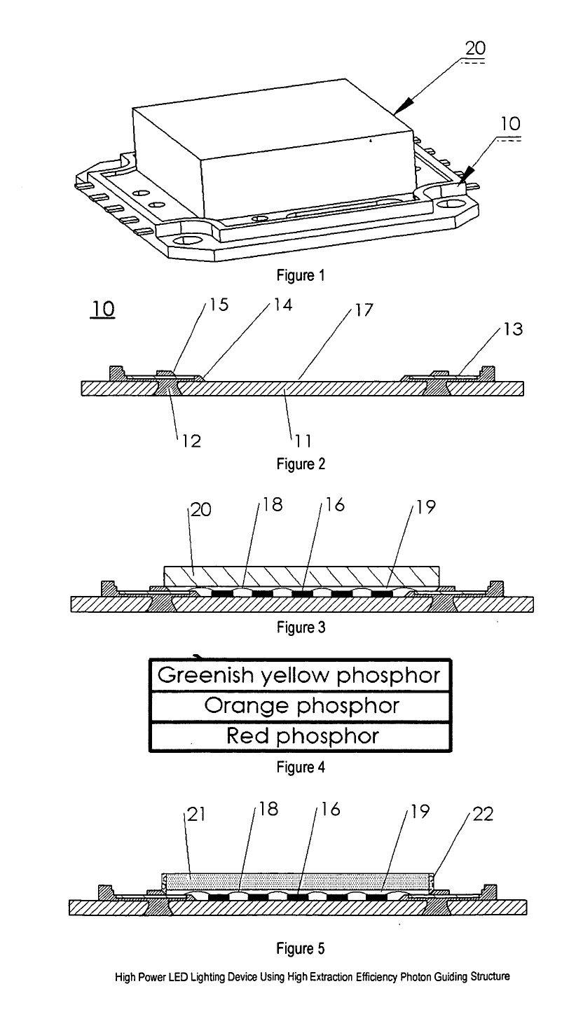

FIG. 1 shows a perspective view of an LED device using high extraction efficiency photon guiding structure. FIG. 2 shows cross-section views of lead-frame 10 shown in FIG. 1. The LED lead-frame consists of a substrate 11, and a supportive structure 12 that is used to hold the substrate 11 and lead-frame 13 together and electrically insulates them. The substrate 11 can be made of high thermal conductive materials such as copper, aluminum, ceramics, and etc. The supportive structure 12 can be made of dielectric materials such as PPA, silicone, epoxy, and etc. It is preferred that the exposed surface of the supportive structure 12 and chip-bonding area 17 are coated with high reflectivity materials such as silver, aluminum, and metal alloys. There are two reflective cups 14 and 15 with its exposed surface forming titled angles of equal or larger than 90 degree with horizontal or substrate surface. The titled angles are used to facilitate light extraction from the LED device.

FIG. 3 shows a cross-sectional view of the LED device shown in FIG. 1. The LED device is made by attaching LED chips 16 onto chip-bonding area 17. The LED chips 16 forming arrays of linear LED chips and are electrically connected to each other by pad-to-pad connection through gold wires 18. After LED chips are bonded to the substrate and electrically connected, encapsulation layer 19 is dispensed into the cups following by attaching a photon-guiding structure 20.

The encapsulation layer 19 is made of transparent materials such as silicone and contains one or more wavelength conversion materials such as green, yellow, orange, and red phosphors. The photon-guiding structure 20 is made of transparent materials such as silicone or PMMA or glass and may contain wavelength conversion materials such as green, yellow, orange, and red phosphors.

Phosphor materials can be blended together and mixed with materials using for making the encapsulation layer 19 and/or the photon-guiding structure 20. The phosphors can be YAG, TAG, silicate based phosphor, etc. For the package using more than one wavelength conversion material, the encapsulation layer 19 contains three phosphor materials in which red, orange, and green-yellow phosphors are embedded in the red, orange, and green-yellow phosphor encapsulation regions, respectively, as shown in FIG. 4. The red phosphor encapsulant is coated on the surface containing LED chips and partially covers LED chips, while the orange phosphor encapsulant resides on top of the red phosphor encapsulant and the green-yellow phosphor encapsulant resides on top of the orange phosphor encapsulant and fully covers LED chips. By this way, double conversion lass by phosphor can be reduced and backwardly phosphor-emitted green and/or yellow light can excite orange or red phosphors. Thus, absorption loss of backwardly emitted light by phosphor can be reduced and the efficiency of the lighting device can be enhanced. This structure also improves efficiency of the device because orange and red phosphor can be excited by back scattered blue, green and yellow light, or backwardly emitted green and yellow light, and emit orange or red light. It thus reduces the absorption loss of backward phosphor-emitted and scattered blue, green and yellow light.

Alternatively, red and orange phosphors are blended together to form red-orange phosphor mixture.

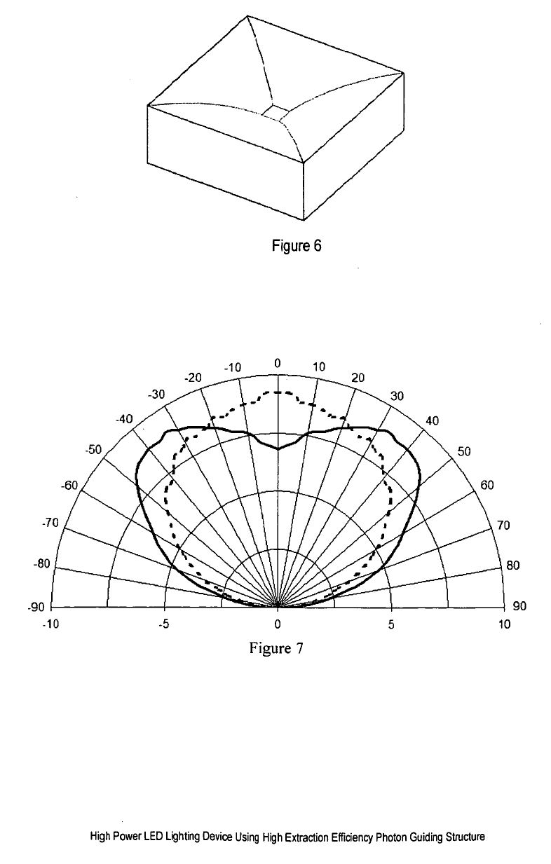

FIG. 5 is a schematic drawing of a light device as another example of an alternative of embodiment of the invention. The LED device shown in FIG. 5 has a supporting structure 22 that is made of transparent materials such as silicone, glass, or PMMA. The supporting structure 22 can be clear or contain phosphor materials and/or fused silica or fused titanium dioxide. The photon-extraction structure 21 is formed by dispensing silicon containing phosphor materials and fuse silica or fused titanium dioxide into the recess of the supporting structure 22.

In order to provide large viewing angle, more light is directed to the side surfaces followed by the emission of light from the side surfaces. To increase emission of light at the side surfaces, a curvature is introduced to the top surface of the encapsulation layer or lens. FIG. 6 shows the alternative photon-guiding structure 20 shown in FIG. 1 and FIG. 2. The top surface of the photon-guiding structure can be a curved surface in one direction or in two directions as shown in FIG. 6. With these structures, there is more light directed to the side surfaces and emitted to the ambient through these side surfaces.

The use of photon-guiding structure 20 increases the efficiency of WLED package, especially when it is compared with a conventional extreme high power package. Four 100-watt WLED samples, two samples of the conventional WLED and two samples of the WLED package of the invention, were made. The WLED packages of the invention provide the average neutral white light lumen output of 9412 lm while the conventional WLED packages provide the average neutral white light lumen output of only 8002 lm.

The photon-guiding structure 20 not only improves the efficiency but also provides light output with large viewing angle that is suitable for generating different pattern of light distribution for different applications such as street lighting, parking lighting, and tunnel lighting when a simple reflector is incorporated with. FIG. 7 shows angular light intensity distribution of light emitted from a conventional extreme high power (100 W) LED package (dash line) and the 100 W LED package of the invention. The light output of the conventional package has a cosine distribution while that of the invented LED package has a butterfly distribution which is more uniform on a flat surface and has a larger viewing angle. The invented LED package has more light emitted at large viewing angle than conventional LED package.

What is claimed is:

1. A high power light emitting device for generating white light with large viewing angle that is used for replacing conventional light in conventional street light fixture or with a reflector to generate different light patterns for different applications such as street lighting, parking lighting and tunnel lighting, comprising:
a lead-frame or COB package;
a plurality of LED-chips that are electrical connected through gold wires forming at least one array of linear LED-chips;
a silicone encapsulation material that directly encapsulates LED chips;
a photon-guiding structure to enhance the extraction of light from the device;
fused silica or fused titanium dioxide to minimize CCT variation in space; and
phosphor materials to partially convert blue light to longer wavelength such as green, yellow, orange, and red.

2. The lead-frame or COB package in claim 1 has a substrate that can be made of metal or ceramic of high thermal conductivity,
Wherein the lead-frame package has PPA housing on top of the metal substrate and forming step-like cavity with the inner and lower portion of the cavity smaller the top portion of the cavity

3. The photon-guiding structure in claim 1 is a pre-made element that is made of silicone, glass, acrylic materials such as PMMA

4. The photon-guiding structure in claim 1 contains one or more phosphor materials, and fused silica or fused titanium dioxide to provide uniform color distribution in space and to prevent settling of phosphor particles that result in higher CCT difference among devices.

5. The photon-guiding structure in claim 1 is a rectangular cube or has its top surface forming an angle of between 45 degree and 90 degree with its side surfaces.

6. The photon-guiding structure in claim 1 has a curved top surface in one direction as it is cut perpendicular to one side surface while it is straight as it is cut perpendicular to the foregoing cut.

7. The photon-guiding structure in claim 1 has a curved top surface when it is cut in both directions perpendicular to the side surfaces.

8. The said silicone encapsulation material in claim 1 contains a mixture of at least one of green, yellow, orange, and red phosphors, and directly encapsulates the said LED chips.

9. Phosphor materials in claim 1 emitting different color types of light is mixed with the said silicone encapsulation material and form multiple phosphor layers with the first layer directly encapsulating the LED chips,
wherein the phosphor material emitting light at a longer wavelength (orange and/or red) is embedded in a layer below the layer that contains a phosphor material emitting light at shorter wavelength of light to avoid/minimize double conversion loss by phosphor materials due to partially absorption of phosphor-emanated green and yellow light by orange or red phosphor materials.

10. Fused silica and fused titanium dioxide have their primary size of few nanometers to 30 nanometers and mixed with phosphor materials.
